(19) United States
(12) Patent Application Publication
(10) Pub. No.: US 2022/0294445 A1
(43) Pub. Date: Sep. 15, 2022

(54) COMPUTER SYSTEM AND INTERFACE CIRCUIT THEREFOR

(71) Applicant: SK hynix Inc., Icheon-si (KR)

(72) Inventor: Hee Jun KIM, Icheon-si (KR)

(21) Appl. No.: 17/534,750

(22) Filed: Nov. 24, 2021

(30) Foreign Application Priority Data
Mar. 9, 2021 (KR) 10-2021-0030510

(51) Int. Cl. H03K 19/017; H03K 19/17788; H03K 19/17784

(52) U.S. Cl. CPC H03K 19/01728; H03K 19/17788; H03K 19/17784

(57) ABSTRACT

A computer system may include a host device including a memory controller and a first interface circuit configured to provide the memory controller with an interface to other devices; and a data storage unit in communication with the host device through a channel and configured to communicate with the host device through a second interface circuit including a termination circuit. The first interface circuit is configured to select between different termination schemes. The first interface circuit is configured to add an addition signal to a transmission signal based on a termination scheme of the termination circuit and transmit the transmission signal with the addition signal to the termination circuit.

### CROSS-REFERENCES TO RELATED APPLICATION

This patent document claims the priority and benefits of Korean application number 10-2021-0030510, filed on Mar. 9, 2021, which is incorporated herein by reference in its entirety as part of the disclosure of this patent document.

### TECHNICAL FIELD

The technology and implementations disclosed in this patent document generally relate to a semiconductor integrated apparatus, and more particularly to a computer system and an interface circuit therefor.

### BACKGROUND

In some computer systems, a host device and a slave device are connected through a channel.

A data storage device may include a memory device that is used as a slave device in a computer system to retain data and a controller that is used as a host device in the computer system to perform write and read operations for writing and reading data to and from the memory device. The memory device and the controller are connected to each other by a transmission line and an interface circuit to transmit and receive data.

Electrical signal waves that are transmitted along the transmission line may be reflected at the termination of the transmission line. The reflected signal waves may be added, as a noise component, to electrical signal waves that are being transmitted, thereby degrading the quality of the transmission signal. Therefore, such a signal refection is undesirable, and a termination circuit can be provided to reduce such undesired signal reflection and to improve the signal quality.

In order to reduce or minimize the reflection of a transmission signal, a termination technique can be used to connect a termination resistor to the termination of a transmission line. The termination of the transmission line may be terminated at a constant voltage level by the termination resistor. Examples of the termination technique includes a center tap termination (CU) scheme and a low tap termination (LTT) scheme depending on a target voltage level of the termination.

With the development of a semiconductor integrated technology, various communication standards for input/output interfaces have been proposed. When input/output interfaces of a transmission device and a reception device do not match each other, the systems at the transmission side and the reception side may not be compatible, or the communication efficiency between the transmission side and the reception side may be reduced.

### SUMMARY

Computer systems and interface circuits are disclosed. A computer system based on some embodiments of the disclosed technology may include: a host device including a memory controller and a first interface circuit configured to provide the memory controller with an interface to other devices; and a data storage unit in communication with the host device through a channel and configured to communicate with the host device through a second interface circuit including a termination circuit, wherein the first interface circuit is configured to select between different termination schemes, and wherein the first interface circuit is configured to add an addition signal to a transmission signal based on a termination scheme of the termination circuit and transmit the transmission signal with the addition signal to the termination circuit.

The computer system based on some embodiments of the disclosed technology may include: a first device including a first interface circuit configured to provide the first device with an interface to other devices; and a second device configured to communicate with the first device through a channel, wherein the first interface circuit is configured to add a first addition signal or a second addition signal different from the first addition signal to the transmission signal, and wherein whether to add the first addition signal or the second addition signal is determined based on a termination voltage level of the channel.

An interface circuit based on some embodiments of the disclosed technology may include: an internal circuit configured to add an addition signal to a first transmission signal to generate a second transmission signal; and an output driver configured to output a second transmission signal; and wherein the interface circuit is in a first device in a computer system that includes the first device and a second device in communication with the first device through a channel, wherein the interface circuit is configured to switch between multiple termination schemes, and wherein the addition signal is added to the first transmission signal based on a termination scheme of a termination circuit connected to a termination of the channel.

In some embodiments of the disclosed technology, a computer system may include a host device including a memory controller and a first interface circuit; and a storage unit connected to the host device through a channel and configured to communicate with the host device through a second interface circuit including a termination circuit, wherein the first interface circuit may be configured to add an addition signal to a transmission signal on the basis of a termination scheme of the termination circuit, and to transmit the transmission signal with the addition signal to the termination circuit.

The computer system based on some embodiments of the disclosed technology may include: a first device including a first interface circuit; and a second device configured to communicate with the first device through a channel, wherein the first interface circuit is configured to add a first addition signal or a second addition signal to the transmission signal on the basis of a termination voltage level of the channel.

In some embodiments of the disclosed technology, an interface circuit of a computer system may include a first device and a second device that communicate with each other through a channel. The interface circuit is configured to add an addition signal to a transmission signal on the basis of a termination scheme of a termination circuit connected to a termination of the channel and to transmit the transmission signal with the addition signal to the termination circuit.

### BRIEF DESCRIPTION OF THE DRAWINGS

FIG. 1 shows an example of a computer system based on some embodiments of the disclosed technology.

FIG. 2 shows an example of an interfacing operation of a termination circuit.

FIG. 3 shows another example an interfacing operation of a termination circuit.

FIG. 4 shows an example of an output device based on some embodiments of the disclosed technology.

FIG. 5 shows an example of the output device based on zo some embodiments of the disclosed technology.

FIG. 6 is a timing diagram of the output device based on some embodiments of the disclosed technology.

FIG. 7 shows an example of a data storage system based on some embodiments of the disclosed technology.

FIG. 8 shows an example of a data processing system based on some embodiments of the disclosed technology.

FIG. 9 shows an example of a data processing system based on some embodiments of the disclosed technology.

FIG. 10 is a diagram illustrating an example of a network system including a data storage device based on some embodiments of the disclosed technology.

FIG. 11 is a block diagram illustrating an example of a nonvolatile memory device included in a data storage device based on some embodiments of the disclosed technology.

### DETAILED DESCRIPTION

Hereinafter, some embodiments of the disclosed technology will be described in more detail with reference to the accompanying drawings.

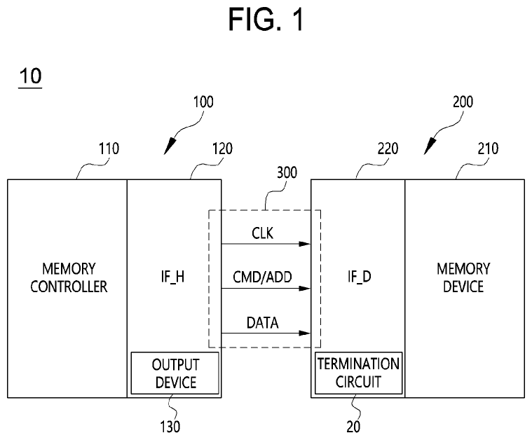

FIG. 1 shows an example of a computer system 10 based on some embodiments of the disclosed technology.

The computer system 10 may include a first device, and a second device connected to the first device through a transmission line. In some implementations, the first device may include a host device 100, the second device may include a storage unit 200 for storing data, and the transmission line may include a channel 300. In some implementations, the computer system 10 may be a data storage device.

The host device 100 may include a memory controller 110 for controlling the storage unit 200 and a first interface circuit 120. In one example, the first interface circuit 120 may include a host-side interface circuit (IF-H). The storage unit 200 may include a memory device 210 and a second interface circuit 220. In one example, the second interface circuit 220 may include a memory-side interface circuit (IF-D).

The host device 100 may include a processor and a plurality of functional blocks, e.g. IPs operating under the control of the processor. The host device 100 may include a system on chip (SoC) that incorporates a plurality of IPs having various functions into a single chip. The host-side interface circuit 120 may also be implemented as a single IP that is integrated into the host device 100.

Example of the memory device 210 may include a volatile memory device such as a dynamic random access memory (DRAM), a static random access memory (SRAM), and a thyristor random access memory (TRAM).

Example of the memory device 210 may also include a nonvolatile memory device such as an electrically erasable and programmable ROM (EEPROM), a NAND flash memory, a NOR flash memory, a phase-change RAM (PRAM), a resistive RAM (ReRAM), a ferroelectric RAM (FRAM), and a spin torque transfer magnetic RAM (STT-MRAM).

The memory device 210 may include a plurality of dies, a plurality of chips, or a plurality of packages. In addition, the memory device 210 may operate as a single-level cell (SLC) that stores one bit of data in one memory cell or a multi-level cell (MLC) that stores multiple bits of data in one memory cell.

The computer system 10 may be implemented in the form of a solid state drive (SSD), a memory card, a universal flash storage (UFS) device, and a similar data storage device.

The channel 300 may be a path that carries data or other signals between the host device 100 and the storage unit 200.

The host device 100 may transmit a clock signal (CLK), a command signal (CMD), an address signal (ADD), and others to the memory-side interface circuit 220 through the host-side interface circuit 120. Furthermore, the host device 100 may transmit data DATA to the memory-side interface circuit 220 through the host-side interface circuit 120.

The storage unit 200 may transmit the data DATA to the host device 100 through the memory-side interface circuit 220.

In some implementations, a path can be shared by multiple storage units. For example, the path that carries the data DATA from the host device 100 to the storage unit 200 may also carry the data DATA from the storage unit 200 to the host device 100. In some implementations, the data DATA transmitted from the host device 100 to the storage unit 200 may be referred to as “write data,” and the data DATA transmitted from the storage unit 200 to the host device 100 may be referred to as “read data.”

The memory-side interface circuit 220 may include a termination circuit 20 to reduce or minimize the undesired reflection of a signal transmitted from the channel 300 for improving the signal quality and thus “terminate” the undesired signal reflection.

The configuration of the termination circuit 20 may vary depending on different storage units 200. In some implementations, the termination circuit 20 may be implemented based on a first termination scheme (center tab termination (CTT) scheme) or a second termination scheme (low tab termination (LTT) scheme) according to various interface standards.

In some embodiments of the disclosed technology, the host-side interface circuit 120 may include an output device 130 that selects and/or amplifies an output signal based on a selection signal determined according to a termination scheme of the termination circuit 20 included in the memory-side interface circuit 220.

In some embodiments of the disclosed technology, when the termination circuit 20 uses the CTT termination scheme, the output device 130 may increase a voltage level of a signal edge of an output signal. For example, a pre-emphasis signal may be added to increase and decrease voltage levels of a rising edge and a falling edge of an output signal.

In some embodiments of the disclosed technology, when the termination circuit 20 uses the LTT termination scheme, the output device 130 may increase a voltage difference between signal edges of an output signal. For example, a de-emphasis signal may be added to increase a voltage difference between a rising edge and a falling edge of an output signal.

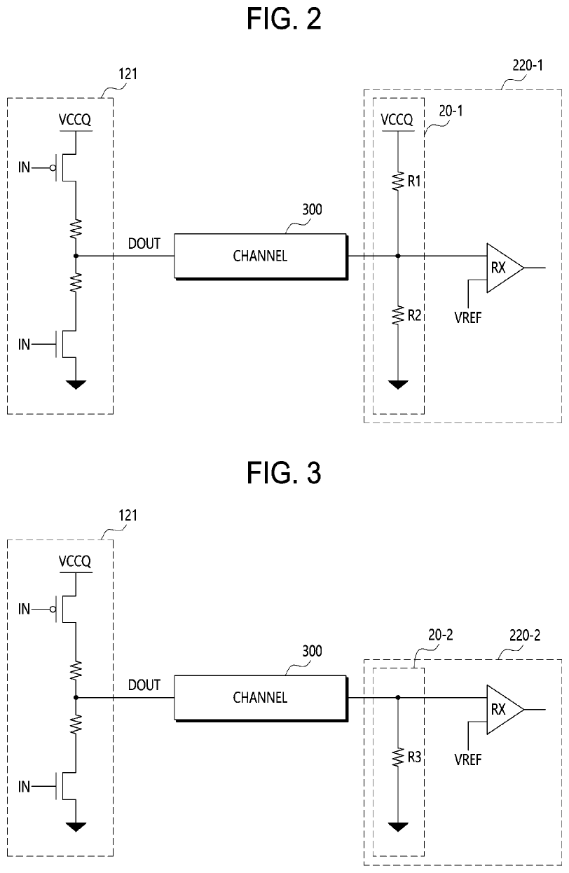

FIG. 2 and FIG. 3 show examples of an interfacing operation of a termination circuit.

FIG. 2 illustrates an example implementation where a termination circuit 20-1 of a memory-side interface circuit 220-1 uses the CTT termination scheme.

The host-side interface circuit 120 of a first device such as the host device 100 may include an output driver 121 that amplifies and/or outputs a transmission signal IN.

A signal applied to an output terminal DOUT of the output driver 121 may be transmitted to a second device such as the storage unit 200 through the channel 300.

The memory-side interface circuit 220-1 may include the termination circuit 20-1 and a reception circuit RX.

The termination circuit 20-1 may include a first termination resistor R1 connected between the termination of the channel 300 and a power supply voltage VCCQ terminal, and a second termination resistor R2 connected between the termination of the channel 300 and a ground voltage terminal. The first termination resistor R1 and the second termination resistor R2 may have the same resistance value as each other, or they may have a similar resistance value.

Accordingly, the termination voltage of the channel 300 is increased or decreased by a predetermined level on the basis of a center level, e.g. a voltage level corresponding to a half of the power supply voltage VCCQ by dividing voltage across the first termination resistor R1 and the second termination resistor R2. According to the CTT termination scheme, the termination voltage of the channel 300 is to be center tap termination (CU).

The reception circuit RX may determine a logic level (or voltage level) of an input signal by comparing a signal received through the termination circuit 20-1 with a reference voltage VREF.

FIG. 3 illustrates an example implementation where a termination circuit 20-2 of a memory-side interface circuit 220-2 uses the LTT termination scheme.

The host-side interface circuit 120 of a first device such as the host device 100 may include the output driver 121 that amplifies and/or outputs the transmission signal IN.

An output signal of the output driver 121 may be transmitted to a second device such as the storage unit 200 through the channel 300.

The memory-side interface circuit 220-2 may include the termination circuit 20-2 and a reception circuit RX.

The termination circuit 20-2 may include a third termination resistor R3 connected between the termination of the channel 300 and a ground voltage terminal. Accordingly, the termination voltage of the channel 300 is increased by a predetermined level on the basis of a lower level, e.g. a ground voltage level. According to the LTT termination scheme, the termination voltage of the channel 300 is to be lower tap termination (LTT).

A high frequency component of a signal that is moving between the host device 100 and the storage unit 200 through the channel 300 may be attenuated, rendering the signal distorted. In order to avoid a potential signal distortion, a pre-emphasis technique and a de-emphasis technique can be used to boost the high frequency component of a transmitted/received data signal.

In the pre-emphasis technique, a first addition signal is added to each of a rising edge and a falling edge of a signal to be transmitted to increase and decrease the voltages of the rising edge and the falling edge, and the first addition signal is generated using the transmission signal IN and an inverted, delayed signal INB_D of the transmission signal IN.

In the de-emphasis technique, a second addition signal is added to each of a rising edge and a falling edge of a signal to be transmitted to increase a voltage difference between the rising edge and the falling edge, and the second addition signal is generated using the transmission signal IN and a delayed signal IN_D of the transmission signal IN.

A signal that is transmitted through the channel 300 may retain its waveform by performing the pre-emphasis on the transmission signal IN before transmission and performing the de-emphasis on the transmitted signal a reception side.

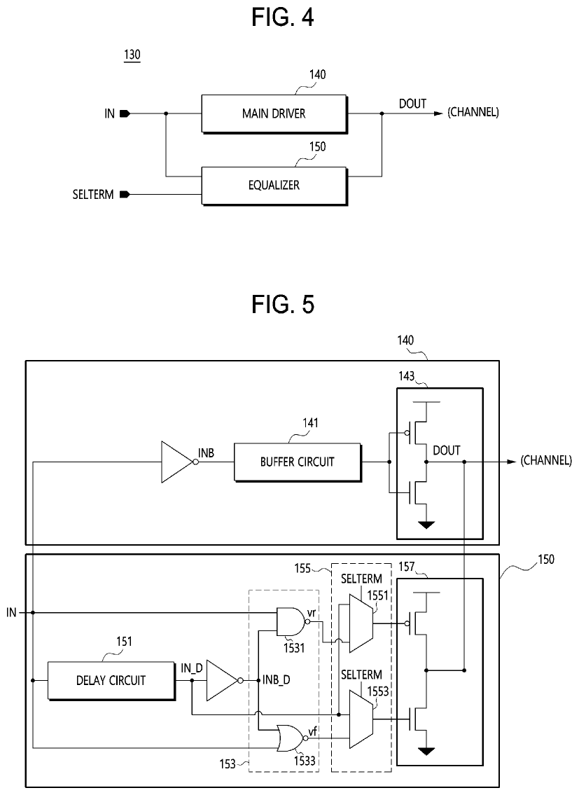

FIG. 4 shows an example of the output device 130 based on some embodiments of the disclosed technology.

Referring to FIG. 4, the output device 130 based on some embodiments of the disclosed technology may include a main driver 140 and an equalizer 150.

The main driver 140 may become activated to provide the transmission signal IN to the output terminal DOUT.

The equalizer 150 may generate a pre-emphasis signal or a de-emphasis signal of the transmission signal IN in response to a termination scheme selection signal SELTERM, and add the generated pre-emphasis signal or de-emphasis signal to the output terminal DOUT.

In some embodiments of the disclosed technology, the termination scheme selection signal SELTERM may be set by a master device that includes the computer system 10 embedded therein, according to the termination scheme of the termination circuit 20 included in the memory-side interface circuit 220 of the storage unit 200.

In some embodiments of the disclosed technology, the termination scheme selection signal SELTERM may be set by the host device 100 when the storage unit 200 is connected to the host device 100.

When the termination circuit 20 uses the CTT termination scheme, the equalizer 150 may generate the pre-emphasis signal by increasing the voltage of the rising edge of the transmission signal IN and decreasing the voltage of the falling edge thereof. In some embodiments of the disclosed technology, when the termination circuit 20 uses the LTT termination scheme, the equalizer 150 may generate the de-emphasis signal by increasing the voltage difference between the rising edge and the falling edge of the transmission signal IN.

FIG. 5 shows an example of the output device based on some embodiments of the disclosed technology.

Referring to FIG. 5, the main driver 140 may include a buffer circuit 141 that stores an inverted signal INB of the transmission signal IN for a preset time period, and a first output unit 143 that amplifies and/or outputs an output signal of the buffer circuit 141 and applies the driven output signal to the output terminal DOUT.

The equalizer 150 may include a delay circuit 151, an edge detection unit 153, an addition signal generation unit 155, and a second output unit 157.

The delay circuit 151 may delay the transmission signal IN for a target time period, for example, 1 unit interval (UI), and output the delayed transmission signal IN_D.

The edge detection unit 153 may include a first detection section 1531 that generates a rising edge detection signal vr in response to the transmission signal IN and the inverted, delayed signal INB_D of the transmission signal IN, and a second detection section 1533 that generates a falling edge detection signal of in response to the transmission signal IN and the inverted, delayed signal INB_D of the transmission signal IN.

The addition signal generation unit 155 may include a first addition signal generation section circuit 1551 that selects any one of the transmission signal IN_D delayed by the delay circuit 151 and the rising edge detection signal vr in response to the termination scheme selection signal SELTERM, and a second addition signal generation section circuit 1553 that selects any one of the delayed transmission signal IN_D and the falling edge detection signal of in response to the termination scheme selection signal SELTERM.

The second output unit 157 may activate an output signal of the addition signal generation unit 155 to add the first addition signal or the second addition signal to the output terminal DOUT.

Accordingly, a pre-emphasis output signal that is obtained by adding the first addition signal to the transmission signal IN, or a de-emphasis output signal that is obtained by adding the second addition signal to the transmission signal IN may be transmitted to a reception-side device through the channel.

In some embodiments of the disclosed technology, the preset time period during which the buffer circuit 141 holds the inverted signal INB of the transmission signal IN may correspond to the time period during which the transmission signal IN passes through the edge detection unit 153 and the addition signal generation unit 155 of the equalizer 150. However, the disclosed technology is not limited thereto.

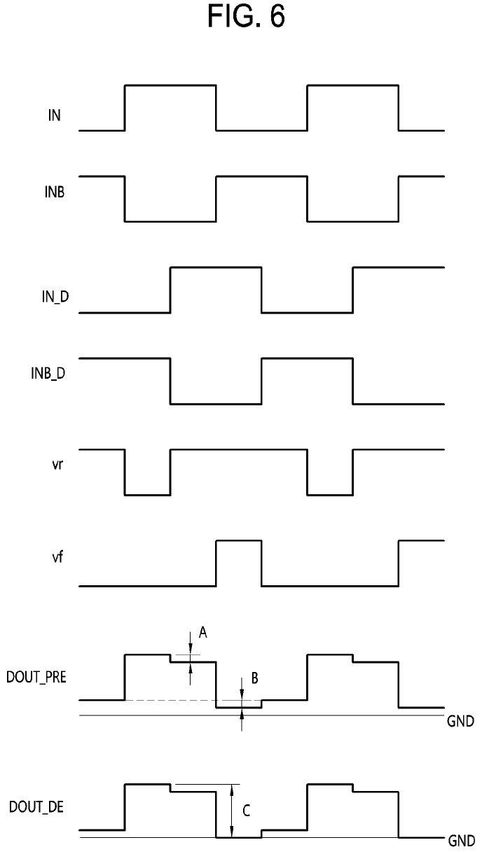

FIG. 6 is a timing diagram of the output device based on some embodiments of the disclosed technology.

Referring to FIG. 5 and FIG. 6, when the reception-side termination circuit 20 is implemented based on the CTT termination scheme, the termination scheme selection signal SELTERM may be enabled at a logic high level. In such a case, the first addition signal generation section 1551 may output the rising edge detection signal vr and the second addition signal generation section 1553 may output the falling edge detection signal vf.

Accordingly, the output signal of the main driver 140 and the pre-emphasis components vr and vf, which are the output signals of the equalizer 150, may be added and a pre-emphasis output signal DOUT_PRE may be applied to the output terminal DOUT.

The voltage level of the pre-emphasis output signal DOUT_PRE may be increased by a predetermined level based on the output signals of the equalizer 150 corresponding to the termination voltage level of the termination circuit 20. In addition, due to the pre-emphasis components vr and vf of the equalizer 150, the pre-emphasis output signal DOUT_PRE has a waveform in which the voltage level of a rising edge increases by a predetermined level A and the voltage level of a falling edge decreases by a predetermined level B.

When the reception-side termination circuit 20 is implemented based on the LTT termination scheme, the termination scheme selection signal SELTERM may be enabled at a logic low level. In such a case, the first addition signal generation section 1551 and the second addition signal generation section 1553 may output the delayed transmission signal IN_D. As a consequence, the second addition signal, which is the output signal of the second output unit 157, may have substantially the same phase as that of the inverted, delayed transmission signal INB_D.

The output signal of the main driver 140 and the second addition signal, which is the output signal of the equalizer 150, may be added and a de-emphasis output signal DOUT_DE may be applied to the output terminal DOUT.

The voltage level of the de-emphasis output signal DOUT_DE may be increased by a predetermined level based on the output signal of the equalizer 150 corresponding to the termination voltage level of the termination circuit 20. In addition, due to the de-emphasis component of the equalizer 150, the de-emphasis output signal DOUT_DE has a waveform in which a difference between the voltage level of a rising edge and the voltage level of a falling edge increases by a predetermined level C.

The host device 100 may generate an output signal using various termination schemes that may be implemented in the termination circuit 20 included in the storage unit 200. Accordingly, the single host device 100 can communicate with different storage units 200 by changing termination schemes depending on various communication standards, which makes it possible to increase the compatibility of the host device 100 and the storage units 200 with the computer system 10 and ensure the integrity of a transmission/reception signal.

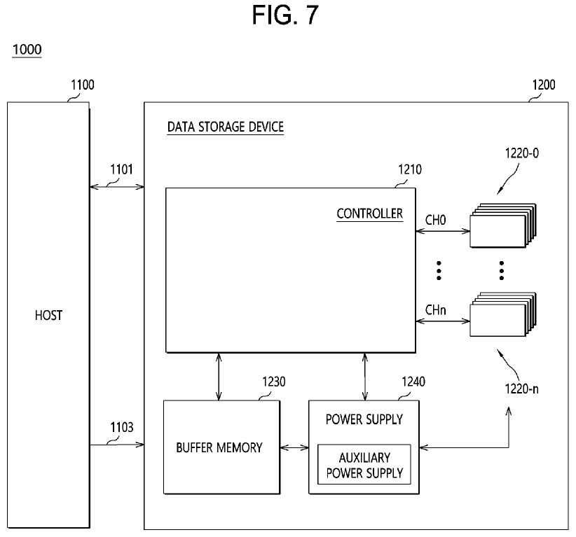

FIG. 7 shows an example of a data storage system 1000, based on some embodiments of the disclosed technology.

Referring to FIG. 7, the data storage 1000 may include a host device 1100 and the data storage device 1200. In some embodiments of the disclosed technology, the data storage device 1200 may be configured as a solid state drive (SSD).

The data storage device 1200 may include a controller 1210, a plurality of nonvolatile memory devices 1220-0 to 1220-n, a buffer memory device 1230, a power supply 1240, a signal connector 1101, and a power connector 1103.

The controller 1210 may control general operations of the data storage device 1200. The controller 1210 may include a host interface unit, a control unit, a random access memory used as a working memory, an error correction code (ECC) unit, and a memory interface unit. In some embodiments of the disclosed technology, the data storage device 1200 may include the interface circuit shown in FIGS. 2 to 5.

The host device 1100 may exchange a signal with the data storage device 1200 through the signal connector 1101. The signal may include a command, an address, data, and so forth.

The controller 1210 may process the signal received from the host device 1100. The controller 1210 may control operations of internal functional blocks according to firmware or software for driving the data storage device 1200.

The buffer memory device 1230 may temporarily store data to be stored in at least one of the nonvolatile memory devices 1220-0 to 1220-n. Further, the buffer memory device 1230 may temporarily store the data read from at least one of the nonvolatile memory devices 1220-0 to 1220-n. The data temporarily stored in the buffer memory device 1230 may be transmitted to the host device 1100 or at least one of the nonvolatile memory devices 1220-0 to 1220-n based on commands and control signals of the controller 1210.

The nonvolatile memory devices 1220-0 to 1220-n may be used as storage media of the data storage device 1200. The nonvolatile memory devices 1220-0 to 1220-n may be coupled with the controller 1210 through a plurality of channels CH0 to CHn, respectively. One or more nonvolatile memory devices may be coupled to one channel. The nonvolatile memory devices coupled to each channel may be coupled to the same signal bus and data bus.

The power supply 1240 may provide power inputted through the power connector 1103 to the controller 1210, the nonvolatile memory devices 1220-0 to 1220-n and the buffer memory device 1230 of the data storage device 1200. The power supply 1240 may include an auxiliary power supply. The auxiliary power supply may supply power to allow the data storage device 1200 to be normally terminated when a sudden power interruption occurs. The auxiliary power supply may include bulk-capacity capacitors sufficient to store the needed charge.

The signal connector 1101 may be configured as one or more of various types of connectors depending on an interface scheme between the host device 1100 and the data storage device 1200.

The power connector 1103 may be configured as one or more of various types of connectors depending on a power supply scheme of the host device 1100.

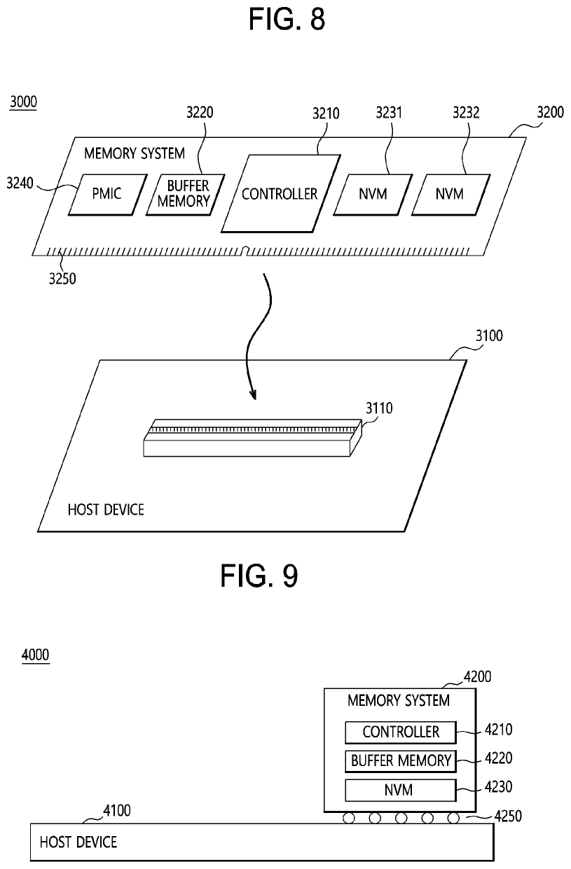

FIG. 8 shows an example of a data processing system 3000 based on some embodiments of the disclosed technology. Referring to FIG. 8, the data processing system 3000 may include a host device 3100 and a memory system 3200.

The host device 3100 may be configured in the form of a board, such as a printed circuit board. Although not shown, the host device 3100 may include internal function blocks for performing the function of a host device.

The host device 3100 may include a connection terminal 3110, such as a socket, a slot, or a connector. The memory system 3200 may be mated to the connection terminal 3110.

The memory system 3200 may be configured in the form of a board, such as a printed circuit board. The memory system 3200 may be referred to as a memory module or a memory card. The memory system 3200 may include a controller 3210, a buffer memory device 3220, nonvolatile memory devices 3231 and 3232, a power management integrated circuit (PMIC) 3240, and a connection terminal 3250.

The controller 3210 may control general operations of the memory system 3200. The data storage device 1200 may include the interface circuit shown in FIGS. 2 to 5.

The buffer memory device 3220 may temporarily store data to be stored in the nonvolatile memory devices 3231 and 3232. Further, the buffer memory device 3220 may temporarily store data read from the nonvolatile memory devices 3231 and 3232. The data temporarily stored in the buffer memory device 3220 may be transmitted to the host device 3100 or the nonvolatile memory devices 3231 and 3232 based on commands and control signals of the controller 3210.

The nonvolatile memory devices 3231 and 3232 may be used as storage media of the memory system 3200.

The PMIC 3240 may provide the power inputted through the connection terminal 3250 to the inside of the memory system 3200. The PMIC 3240 may manage the power of the memory system 3200 based on commands and control signals of the controller 3210.

The connection terminal 3250 may be coupled to the connection terminal 3110 of the host device 3100. Through the connection terminal 3250, signals such as commands, addresses, and data, and power may be transferred between the host device 3100 and the memory system 3200. The connection terminal 3250 may be configured as one or more types depending on an interface scheme between the host device 3100 and the memory system 3200. The connection terminal 3250 may be disposed on a side of the memory system 3200.

FIG. 9 shows an example of a data processing system 4000 based on some embodiments of the disclosed technology. Referring to FIG. 9, the data processing system 4000 may include a host device 4100 and a memory system 4200.

The host device 4100 may be configured in the form of a board, such as a printed circuit board. Although not shown in the drawings, the host device 4100 may include internal functional blocks for performing the function of a host device.

The memory system 4200 may be configured in the form of a surface-mounted type package. The memory system 4200 may be incorporated into the host device 4100 through solder balls 4250. The memory system 4200 may include a controller 4210, a buffer memory device 4220, and a nonvolatile memory device 4230.

The controller 4210 may control general operations of the memory system 4200. The data storage device 1200 may include the interface circuit shown in FIGS. 2 to 5.

The buffer memory device 4220 may temporarily store data to be stored in the nonvolatile memory device 4230. Further, the buffer memory device 4220 may temporarily store data read from the nonvolatile memory device 4230. The data temporarily stored in the buffer memory device 4220 may be transmitted to the host device 4100 or the nonvolatile memory device 4230 based on commands and control signals of the controller 4210.

The nonvolatile memory device 4230 may be used as the storage medium of the memory system 4200.

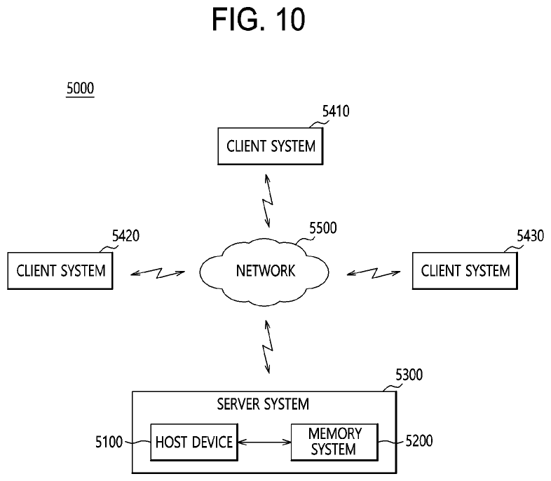

FIG. 10 is a diagram illustrating an example of a network system 5000 including a data storage device based on some embodiments of the disclosed technology. Referring to FIG. 10, the network system 5000 may include a server system 5300 and a plurality of client systems 5410, 5420, and 5430, which are in communication with each other through a network 5500.

The server system 5300 may service data in response to requests from the plurality of client systems 5410 to 5430. In an example implementation, the server system 5300 may store the data provided by the plurality of client systems 5410 to 5430. In another example implementation, the server system 5300 may provide data to the plurality of client systems 5410 to 5430.

The server system 5300 may include a host device 5100 and a memory system 5200. The memory system 5200 may be configured as the memory system 10 shown in FIG. 1, the data storage device 1200 shown in FIG. 7, the memory system 3200 shown in FIG. 8, or the memory system 4200 shown in FIG. 9.

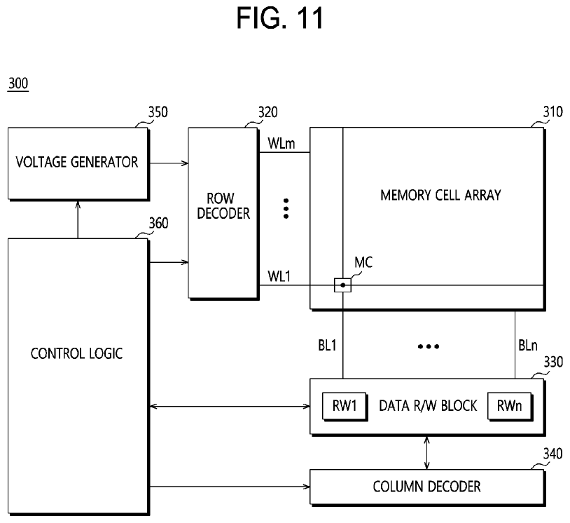

FIG. 11 is a block diagram illustrating an example of a nonvolatile memory device 300 included in a data storage device, such as the data storage device 10 based on some embodiments of the disclosed technology. Referring to FIG. 11, the nonvolatile memory device 300 may include a memory cell array 310, a row decoder 320, a data read/write block 330, a column decoder 340, a voltage generator 350, and a control logic 360.

The memory cell array 310 may include memory cells MC which are arranged at areas where word lines WL1 to WLm and bit lines BL1 to BLn are arranged in rows and columns.

The memory cell array 310 may include a three-dimensional memory array. The three-dimensional memory array, for example, has a stacked structure by perpendicular direction to the flat surface of a semiconductor substrate. Moreover, the three-dimensional memory array includes NAND memory cell strings, each of which includes memory cells vertically stacked on a semiconductor substrate.

The structure of the three-dimensional memory array is not limited to the structure discussed above. The memory array structure can be formed in a highly integrated manner in a horizontal direction and a vertical direction. In some embodiments of the disclosed technology, in the NAND strings of the three-dimensional memory array memory cells are arranged in the horizontal and vertical directions with respect to the surface of the semiconductor substrate. The memory cells may be spaced apart from each other by different distances.

The row decoder 320 may be coupled with the memory cell array 310 through the word lines WL1 to WLm. The row decoder 320 may operate based on commands and control signals of the control logic 360. The row decoder 320 may decode an address provided by an external device (not shown). The row decoder 320 may select and activate the word lines WL1 to WLm, based on a decoding result. For instance, the row decoder 320 may provide a word line voltage, provided by the voltage generator 350, to the word lines WL1 to WLm.

The data read/write block 330 may be coupled with the memory cell array 310 through the bit lines BL1 to BLn. The data read/write block 330 may include read/write circuits RW1 to RWn, respectively, corresponding to the bit lines BL1 to BLn. The data read/write block 330 may operate based on commands and control signals of the control logic 360. The data read/write block 330 may operate as a write driver or a sense amplifier, according to an operation mode. For example, the data read/write block 330 may operate as a write driver, which stores data provided by the external device in the memory cell array 310 in a write operation. For another example, the data read/write block 330 may operate as a sense amplifier, which reads out data from the memory cell array 310 in a read operation.

The column decoder 340 may operate based on commands and control signals of the control logic 360. The column decoder 340 may decode an address provided by the external device. The column decoder 340 may couple the read/write circuits RW1 to RWn of the data read/write block 330, respectively corresponding to the bit lines BL1 to BLn, with data input/output lines or data input/output buffers, based on a decoding result.

The voltage generator 350 may generate voltages to be used in internal operations of the nonvolatile memory device 300. The voltages generated by the voltage generator 350 may be applied to the memory cells of the memory cell array 310. For example, a program voltage generated in a program operation may be applied to a word line of memory cells for which the program operation is to be performed. For another example, an erase voltage generated in an erase operation may be applied to a well area of memory cells for which the erase operation is to be performed. For still another example, a read voltage generated in a read operation may be applied to a word line of memory cells for which the read operation is to be performed.

The control logic 360 may control general operations of the nonvolatile memory device 300, based on control signals provided by the external device. For example, the control logic 360 may control operations of the nonvolatile memory device 300 such as read, write, and erase operations of the nonvolatile memory device 300.

The technical features disclosed in this patent document can be implemented in various configurations or ways and the disclosed embodiments are merely examples of certain implementations. Variations and enhancements of the disclosed embodiments and other embodiments can be made based on what is disclosed and/or illustrated in this patent document.

What is claimed is:

1. A computer system comprising:
a host device including a memory controller and a first interface circuit configured to provide the memory controller with an interface to other devices; and
a data storage unit in communication with the host device through a channel and configured to communicate with the host device through a second interface circuit including a termination circuit,
wherein the first interface circuit is configured to select between different termination schemes, and
wherein the first interface circuit is configured to add an addition signal to a transmission signal based on a termination scheme of the termination circuit and transmit the transmission signal with the addition signal to the termination circuit.

2. The computer system according to claim 1, wherein the termination circuit is configured to increase or decrease a termination voltage of the channel by a voltage level corresponding to a half of a power supply voltage, and
the first interface circuit is configured to add a first addition signal to each of a rising edge and a falling edge of the transmission signal in response to a termination scheme selection signal.

3. The computer system according to claim 2, wherein the first interface circuit comprises:
an edge detection unit configured to detect the rising edge and the falling edge and output a rising edge detection signal and a falling edge detection signal; and
an addition signal generation unit configured to output the rising edge detection signal and the falling edge detection signal as the first addition signal in response to the termination scheme selection signal.

4. The computer system according to claim 1, wherein the termination circuit is configured to increase a termination voltage of the channel by a voltage level that is set based on a ground voltage level, and
the first interface circuit is configured to add a second addition signal for increasing a voltage difference between the rising edge and the falling edge of the transmission signal in response to a termination scheme selection signal.

5. The computer system according to claim 4, wherein the first interface circuit includes an addition signal generation unit configured to generate a second transmission signal by delaying an inverted first transmission signal for a first time period, as the second addition signal in response to the termination scheme selection signal.

6. The computer system according to claim 5, wherein the first time period corresponds to one unit interval of the transmission signal.

7. A computer system comprising:
a first device including a first interface circuit configured to provide the first device with an interface to other devices; and
a second device configured to communicate with the first device through a channel,
wherein the first interface circuit is configured to add a first addition signal or a second addition signal different from the first addition signal to the transmission signal, and wherein whether to add the first addition signal or the second addition signal is is determined based on a termination voltage level of the channel.

8. The computer system according to claim 7, wherein the termination voltage level is obtained by increasing or decreasing a voltage level corresponding to a half of a power supply voltage by a predetermined voltage level, and
the first interface circuit is configured to increase a voltage level of each of the rising edge and the falling edge of the transmission signal in response to the termination scheme selection signal corresponding to the termination voltage level.

9. The computer system according to claim 7, wherein the termination voltage level is obtained by increasing a ground voltage level by a predetermined voltage level, and
the first interface circuit is configured to add a second addition signal to increase a voltage difference between the rising edge and the falling edge of the transmission signal in response to the termination scheme selection signal corresponding to the termination voltage level.

10. An interface circuit comprising:
an internal circuit configured to add an addition signal to a first transmission signal to generate a second transmission signal; and
an output driver configured to output a second transmission signal; and
wherein the interface circuit is in a first device in a computer system that includes the first device and a second device in communication with the first device through a channel,
wherein the interface circuit is configured to switch between multiple termination schemes, and
wherein the addition signal is added to the first transmission signal based on a termination scheme of a termination circuit connected to a termination of the channel.

11. The interface circuit according to claim 10, wherein the termination circuit is configured to increase or decrease a termination voltage of the channel by a voltage level corresponding to a half of a power supply voltage, and
the interface circuit is configured to add a first addition signal to each of a rising edge and a falling edge of the first transmission signal in response to a termination scheme selection signal.

12. The interface circuit according to claim 11, wherein the interface circuit comprises:
an edge detection unit configured to detect the rising edge and the falling edge and output a rising edge detection signal and a falling edge detection signal; and
an addition signal generation unit configured to output the rising edge detection signal and the falling edge detection signal as the first addition signal in response to the termination scheme selection signal.

13. The interface circuit according to claim 10, wherein the termination circuit is configured to increase a termination voltage of the channel by a voltage level that is set based on a ground voltage level, and
the interface circuit is configured to add a second addition signal for increasing a voltage difference between the rising edge and the falling edge of the first transmission signal in response to the termination scheme selection signal.

14. The interface circuit according to claim 13, wherein the interface circuit includes an addition signal generation unit configured to generate the second transmission signal by delaying an inverted first transmission signal for a first time period, as the second addition signal in response to the termination scheme selection signal.

15. The interface circuit according to claim 14, wherein the first time period corresponds to one unit interval of the transmission signal.
